(19) United States
(12) Patent Application Publication
(10) Pub. No.: US 2006/0166469 A1
(43) Pub. Date: Jul. 27, 2006

(54) Method of laser beam maching and laser beam machining apparatus

(76) Inventors: Junichiro Nakayama, Souraku-gun, Kyoto (JP); Shinya Okazaki, Nara-shi, Nara (JP)

Correspondence Address: EDWARDS & ANGELL, LLP, P.O. BOX 55874, BOSTON, MA, 02205, US

(21) Appl. No.: 10/526,855

(22) PCT Filed: Sep. 3, 2003
(86) PCT No.: PCT/JP03/11229

§ 371 Date: Feb. 7, 2006

(30) Foreign Application Priority Data
Sep. 4, 2002 (JP) 2002-259318

(51) Int. Cl. H01L 21/20

(52) U.S. Cl. 438/487; 257/213

(57) ABSTRACT

An object of the invention is to credibly crystallize an amorphous material for use as a semiconductor material and effect crystallization to a region of desired scope. A first region drawn on a surface of a layer of amorphous material formed on the surface layer of sample (21) is irradiated with laser beam to thereby effect melting, solidification and crystallization of the amorphous material. A second region drawn on the surface of the layer of amorphous material so as to partially overlap the first region is determined, and the second region is irradiated with laser beam to thereby melt the amorphous material within the second region. At the time of solidification of the molten amorphous material, epitaxial growth with the use of the crystal of the first region as a seed crystal is carried out to thereby attain crystallization. Shifting of the first and second regions to be irradiated with laser beam on the surface of the layer of amorphous material and irradiation with laser beam are repeated until the region of crystallization of the amorphous material reaches a desired scope.

### TECHNICAL FIELD

The present invention relates to a laser processing method and laser processing apparatus that crystallize an amorphous material used as a semiconductor material in, for example, semiconductor devices, by irradiation of a laser beam.

### BACKGROUND ART

Semiconductor devices can be formed of single crystal silicon (Si) which serves also as a substrate or be formed as a silicon (Si) thin film laminated on a glass substrate. Such semiconductor devices are provided in, for example, image sensors or active matrix liquid crystal displays. Semiconductor devices provided in liquid crystal displays (LCD: liquid crystal display) are constituted by, for example, an array of thin film transistors (TFT: thin film transistor) regularly formed on a transparent substrate, and therein each of the TFTs serves as a pixel controller.

There is a demand for LCDs having low power consumption, high response rate, higher brightness, and higher resolution. The improvement of the performance of LCDs depends significantly on the improvement of the performance of TFTs serving as pixel controllers, in particular, switching characteristics. The switching characteristics of TFTs can be improved by improving the mobility of electrons serving as carriers in transistors. It is known that the electron mobility in transistors is higher when Si, which is a transistor material, is crystalline than amorphous. For this reason, although TFTs often used in general purpose LCDs have been formed in a thin amorphous Si film, crystalline Si is replacing the amorphous Si.

An Si polycrystalline structure is formed by, for example, a method of melting amorphous Si by irradiation of a laser beam emitted from an excimer laser to crystallize Si during solidification. However, when Si is simply melted and solidified, a large number of small crystal grains having different sizes and different crystal orientations are formed randomly.

When a large number of small crystal grains are formed, a large number of grain boundaries defining crystal grains are formed, so that these crystal boundaries trap electrons and block electron transfer, and thus an improvement effect of crystallization on the electron mobility is not provided sufficiently. Furthermore, in small crystals with different sizes and orientations, the electron mobility is different from crystal to crystal, that is, a large number of TFTs provided with different operation performance are formed, and thus non-uniformity in the device characteristics occurs in the TFT array. Therefore, it is necessary to form a TFT array having uniform device characteristics in order to further improve the performance of LCDs, and it is necessary to enlarge the crystalline region of Si forming TFTs and to increase the size of crystal grains that are crystallized to the extent possible in order to achieve uniformity in the characteristics of TFTs.

One of conventional techniques addressing these problems will be described below. FIG. 11 is a system diagram schematically showing a structure of a laser processing apparatus 1 used in conventional techniques. The laser processing apparatus 1 includes an excimer laser 2 serving as a light source that emits a pulsed laser beam, a plurality of mirrors 3 that reflect and redirect the laser beam emitted from the excimer laser 2, a variable attenuator 4, a variable focus field lens 5, a projection mask 6 that lets the laser beam having been transmitted through the variable focus field lens 5 pass through while limiting the laser beam to a predetermined pattern, an imaging lens 7 that forms an image on a sample 8 with the laser beam having passed through the projection mask 6, and a stage 9 on which the sample 8 can be mounted and with which the sample 8 can be moved.

This conventional technique crystallizes the sample 8 in a following manner by using the laser processing apparatus 1 shown in FIG. 11. The method for forming a crystalline region extending in the lateral direction of a film of a semiconductor material on a substrate, which is the sample 8, includes: (a) a step of exposing a first portion of the film and melting the semiconductor material in the first portion throughout the entire thickness by pulsed emission inducing heat in the semiconductor material, (b) a step of solidifying a semiconductor in the first portion, and forming at least one semiconductor crystal in a boundary portion of the first portion, to define the first portion as the previous portion for the next process, (c) a step of moving step by step from the previous portion in a moving direction and exposing another portion (second portion) of a semiconductor that partially overlaps the at least one semiconductor crystal, (d) a step of solidifying the molten semiconductor material in the second portion, and growing the semiconductor crystal in the moving direction to enlarge the semiconductor crystal, and (e) repeating a combination of the steps c and d, and defining another portion of each step as the previous portion for the next step, until a desired crystalline region is formed (See JP 2000-505241A (Tokuhyo), pp. 15-16, FIG. 1).

The above-described conventional technique has problems as below. Since one portion of a semiconductor material is exposed to pulsed emission only once, when the focus is displaced by fluctuation of the power of a light source for emitting pulses or by vibration of the apparatus, and sufficient heat is not induced in the semiconductor martial, then the semiconductor material may not be crystallized, or a crystal grain may be small even when crystallized.

Furthermore, in order to enlarge a crystal grain that is obtained by crystallization, a region exposed to pulsed emission needs to be in the shape of a chevron, or a region that is to be crystallized needs to be patterned in advance. When the exposed region is in the shape of a chevron, a crystal grows only within an area spreading from the peak of the chevron shape. When the region that is to be crystallized is patterned in advance, the entire substrate is difficult to crystallize.

### DISCLOSURE OF INVENTION

An object of the invention is to provide a laser processing method and laser processing apparatus that can reliably crystallize an amorphous material used as a semiconductor material, and that can crystallize a region of a desired area.

The invention is directed to a laser processing method for crystallizing an amorphous material by irradiating a layer formed of the amorphous material constituting a substrate or a layer formed of an amorphous material on a substrate with a laser beam, comprising:

irradiating a first region defined on a surface of the layer formed of the amorphous material with a laser beam so that the amorphous material in the first region is melted,

solidifying and crystallizing the molten amorphous material in the first region,

irradiating a second region that is defined on the surface of the layer formed of the amorphous material and overlaps the first region in a predetermined portion thereof with a laser beam so that the amorphous material in the second region is melted,

solidifying and crystallizing the molten amorphous material in the second region,

moving a region that is to be irradiated with a laser beam in a predetermined direction by a predetermined distance, and newly defining a first region on the surface of the layer formed of the amorphous material so as to partially overlap a immediately previous second region, and

repeating irradiation of the laser beam on the surface of the layer formed of the amorphous material and movement of a region that is to be irradiated with the laser beam until a crystalline region of the amorphous material reaches a desired size.

Furthermore, the invention is characterized in that the first and the second regions are defined as a rectangle shape on the surface of the layer formed of the amorphous material.

Furthermore, the invention is characterized in that the first and the second regions on the surface of the layer formed of the amorphous material are defined as a sawtooth shape.

Furthermore, the invention is characterized in that the first and the second regions are defined on the surface of the layer formed of the amorphous material as an arch shape.

Furthermore, the invention is characterized in that the first region and the second region intersect with each other.

Furthermore, the invention is characterized in that the amorphous material in a molten state in the first and/or the second regions is irradiated with an additional laser beam.

Furthermore, the invention is directed to a laser processing apparatus which crystallizes an amorphous material by irradiating a layer formed of the amorphous material constituting a substrate or a layer formed of an amorphous material on a substrate with a laser beam, comprising:

a light source for emitting a laser beam,

a first projection mask provided in an optical path of a laser beam formed between the light source and the layer formed of the amorphous material so as to define a first region on a surface of the layer formed of the amorphous material by letting the laser beam emitted from the light source pass through, and

a second projection mask provided in an optical path of a laser beam formed between the light source and the layer formed of the amorphous material so as to define a second region on the surface of the layer formed of the amorphous material by letting the laser beam emitted from the light source pass through.

Furthermore, the invention is characterized in that the laser light source includes a first laser light source for emitting a laser beam for irradiating the first region and a second laser light source for emitting a laser beam for irradiating the second region.

Furthermore, the invention is characterized in that the laser processing apparatus further comprises an additional laser light source for emitting a laser beam for irradiating the amorphous material in a molten state in the first and/or the second regions,

wherein a wavelength of laser light emitted from the additional laser light source is longer than a wavelength of laser light emitted from said laser light source.

### BRIEF DESCRIPTION OF DRAWINGS

Other and further objects, features, and advantages of the invention will be more explicit from the following detailed description taken with reference to the drawings wherein:

FIG. 1 is a system diagram schematically showing a structure of a laser processing apparatus 10, which is an embodiment of the invention.

FIG. 2 is a plan view showing the shapes of a first and a second projection mask 17 and 18 provided in the laser processing apparatus 10 shown in FIG. 1.

FIG. 3 is a cross-sectional view schematically showing a structure of a sample 21.

FIGS. 4A to 4C are diagrams schematically showing a crystallization process on an a-Si film 29 performed by irradiation of a laser beam.

FIG. 5 is a plan view showing the shape of an alternative projection mask 33.

FIG. 6 is a plan view showing the shapes of a third and a fourth projection mask 35 and 36 provided in a laser processing apparatus, which is a second embodiment of the invention.

FIGS. 7A1 to 7E2 are diagrams schematically showing a crystallization process on the a-Si film 29 performed by irradiation of a laser beam, in the case where a first region 31 and a second region 32 intersect each other.

FIG. 8 is a view showing the shapes of a fifth and a sixth projection mask 45 and 46 in which opening portions 43 and 44 are formed in an arch shape.

FIG. 9 is a system diagram schematically showing a structure of a laser processing apparatus 50, which is a third embodiment of the invention.

FIG. 10 is a system diagram schematically showing a structure of a laser processing apparatus 60, which is a fourth embodiment of the invention.

FIG. 11 is a system diagram schematically showing a structure of a laser processing apparatus 1 used in conventional techniques.

### BEST MODE FOR CARRYING OUT THE INVENTION

Now referring to the drawings, preferred embodiments of the invention are described below.

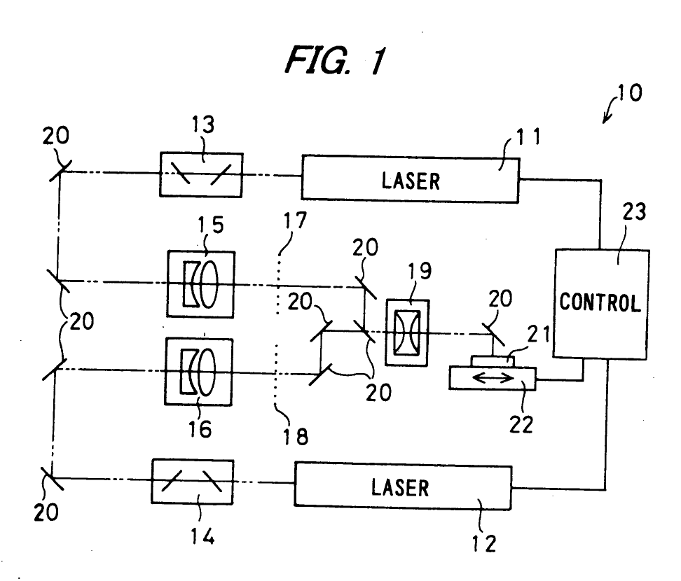

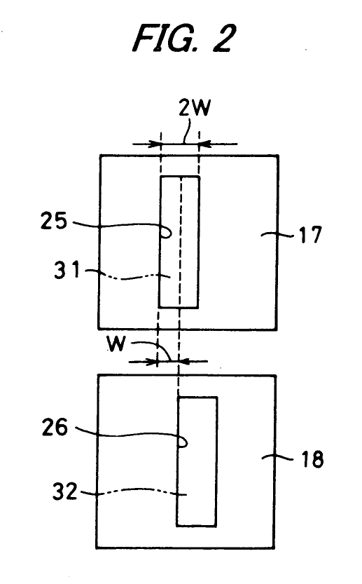

FIG. 1 is a system diagram schematically showing a structure of a laser processing apparatus 10, which is an embodiment of the invention. FIG. 2 is a plan view showing the shapes of a first and a second projection mask 17 and 18 provided in the laser processing apparatus 10 shown in FIG. 1. The laser processing apparatus 10 includes a first and a second laser light source 11 and 12 that emit laser beams, a first and a second variable attenuator 13 and 14 and a first and a second variable focus field lens 15 and 16 that are provided in the optical paths of the laser beams emitted from the first and the second laser light sources 11 and 12 respectively, a first and a second projection mask 17 and 18 through which the laser beams having been transmitted through the first and the second variable focus field lenses 15 and 16 pass, an imaging lens 19, a plurality of mirrors 20 that are provided so as to reflect the laser beams and redirect the optical paths thereof, a sample 21 that is to be crystallized by irradiation of a laser beam, a stage 22 on which the sample 21 is mounted, and control means 23 for controlling the power of the first and the second laser light sources 11 and 12 and for controlling a drive of the stage 22.

For the first and the second laser light sources 11 and 12, an XeCl excimer laser, which is a gas laser, having a wavelength of 308 nm can be used. Such an excimer laser is available from, for example, Compex 301 (manufactured by Lambda Physic). The first and the second variable attenuators 13 and 14 serve as filters that are capable of variably setting the transmission of laser beams, and can adjust the irradiance of laser beams emitted from the first and the second laser light sources 11 and 12.

The first and the second variable focus field lenses 15 and 16 are lenses for focusing a laser beam and adjusting a focus. The first and the second projection masks 17 and 18 are constituted by, for example, synthetic quartz on which a chromium thin film is patterned. In this embodiment, a first and a second rectangular opening portion 25 and 26 are formed in the first and the second projection masks 17 and 18, respectively.

The first and the second projection masks 17 and 18 are provided in the optical paths of the laser beams emitted from the first and the second laser light sources 11 and 12, and define a first and a second region, which will be described below, on a surface of the sample 21 by letting light beams that have been transmitted through the first and the second variable focus field lenses 15 and 16 pass through.

The imaging lens 19 forms images of the first and the second opening portions 25 and 26 on the surface of the sample 21 with the laser beams. The stage 22 is provided with driving means, so that the mounted sample 21 can be moved in the horizontal direction along with the X-Y axes in a two-dimensional plane and rotated.

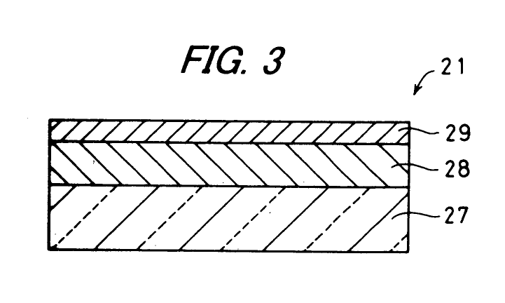

FIG. 3 is a cross-sectional view schematically showing a structure of the sample 21. In the sample 21, an SiO₂ film 28 is laminated on one surface of a transparent substrate 27, and an amorphous silicon (a-Si) film 29 is further laminated on the surface of the SiO₂ film 28. Herein, the a-Si film 29 is a layer formed of an amorphous material. In this embodiment, the thickness of the SiO₂ film 28 is 100 nm, and the thickness of the a-Si film 29 is 50 nm. The SiO₂ film 28 and the a-Si film 29 are each laminated to such a thickness by, for example, plasma enhanced chemical vapor deposition (PECVD), vapor-deposition, or sputtering.

The control means 23 is a processing circuit that can be realized by, for example, a microcomputer provided with a CPU (central processing unit). The first and the second laser light sources 11 and 12 and the stage 22 are electrically connected to the control means 23. The control means 23 controls the width and the cycle of oscillation pulses of laser beams emitted from the first and the second laser light sources 11 and 12, and controls the driving of the stage 22, that is, the position of the sample 21 mounted on the stage 22.

The width and the cycle of oscillation pulses of laser beams can be controlled, for example, by creating a table of the width and the cycle of oscillation pulses that are predetermined for each condition for crystallization process of the sample 21, by providing the control means 23 with, for example, a RAM (random access memory) storing the table, and by giving control signals based on the table information read out from the RAM to the first and the second laser light sources 11 and 12. The driving of the stage 22 may be controlled by the numerical control (NC) based on information given to the control means 23 in advance, or may be controlled by providing a position sensor for detecting the position of the sample 21 and controlling in response to a detection output from the position sensor.

A laser beam emitted from the first laser light source 11 in response to a control signal from the control means 23 passes through the first variable attenuator 13, by which the irradiance is adjusted, is transmitted through the first variable focus field lens 15, passes through the first opening portion 25 of the first projection mask 17, and is irradiated on the a-Si film 29 on the sample 21 by the imaging lens 19. This laser beam emitted from the first laser light source 11 and reaching the a-Si film 29 on the sample 21 passes through the first opening portion 25 of the first projection mask 17 as described above, and thus only the first region defined in the shape of a rectangle on the a-Si film 29 is irradiated.

In a similar manner to the above, a laser beam emitted from the second laser light source 12 passes through the second variable attenuator 14, is transmitted through the second variable focus field lens 16, passes through the second opening portion 26 of the second projection mask 18, and is irradiated on the a-Si film 29 on the sample 21 by the imaging lens 19. This laser beam emitted from the second laser light source 12 and reaching the a-Si film 29 on the sample 21 passes through the second opening portion 26 of the second projection mask 18 as described above, and thus only the second region defined in the shape of a rectangle on the a-Si film 29 is irradiated.

Referring to FIG. 2 again, the first and the second regions 31 and 32 defined on the a-Si film 29 will be described. The first and the second opening portions 25 and 26 of the first and the second projection masks 17 and 18 shown in FIG. 2 are formed in such a manner that the length thereof in the lateral direction is 2W.

In a state where images of the first and the second opening portions 25 and 26 are formed on the a-Si film 29 in the same magnification as shown in FIG. 2, with respect to the first region 31 defined on the a-Si film 29 by the first opening portion 25, the second region 32 defined on the a-Si film 29 by the second opening portion 26 is set so as to be displaced by a distance W in the lateral direction of the first region 31. More specifically, the first and the second projection masks 17 and 18 are provided in the optical paths of laser beams emitted from the first and the second laser light sources 11 and 12 in such a manner that the first region 31 and the second region 32 defined on the a-Si film 29 are located as described above. Hereinafter, the distance W may be referred to as “offset value”.

When the reduction ratio of images of the first and the second opening portions 25 and 26 formed on the a-Si film 29 by the imaging lens 19 with respect to the original sizes is denoted by n, the length of the first and the second regions 31 and 32 in the lateral direction can be given by 2W×n, and the offset value of the second region 32 with respect to the first region 31 can be given by W×n.

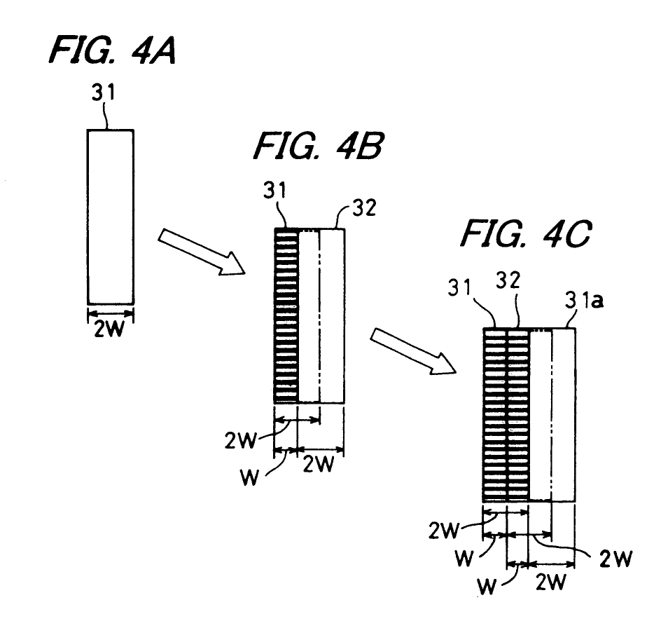

Hereinafter, a laser processing method that crystallizes the a-Si film 29, which is an amorphous material, by irradiation of a laser beam will be described. FIGS. 4A to 4C are diagrams schematically showing a crystallization process on the a-Si film 29 performed by irradiation of a laser beam.

FIG. 4A shows a state in which with a laser beam emitted from the first laser light source 11 is irradiated on the first region 31 defined on a surface of the a-Si film 29, and a-Si in the first region 31 is melted by irradiation of the laser beam. In this embodiment, the first region 31 is defined in the shape of a rectangle, so that the temperature gradient formed in the lateral direction is larger than the temperature gradient formed in the longitudinal direction when a-Si is melted and solidified. Therefore, the a-Si crystallizes and the crystal grows in the lateral direction having a large temperature gradient.

FIG. 4B shows a state in which a laser beam is irradiated on the second region 32 defined in a position obtained by displacing a region to be irradiated with a laser beam by the offset value W in the lateral direction of the first region 31 with respect to the a-Si having crystallized in the first region 31, and a-Si in the second region 32 is melted. When the molten a-Si in the second region 32 solidifies and crystallizes, a portion of the lateral direction W overlapping the first region 31 is melted again, but the crystal that has crystallized in the other portion of the offset W in the first region 31 remains as the seed crystal, and thus the crystallization progresses epitaxially from this seed crystal to the second region 32.

Next, the stage 22, that is, the sample 21 is moved in such a manner that a first region 31a defined on the a-Si film 29 by the first projection mask is further displaced by the offset value W from the second region 32 in the lateral direction, with the control means 23. FIG. 4C shows a state in which a laser beam is irradiated on the first region 31a newly defined on the a-Si film 29 by moving the sample 21, and the a-Si in the first region 31a is melted. In a similar manner to that in the second region 32, in the new first region 31a, the crystal that has crystallized in the second region 32 serves as the seed crystal, and thus the crystallization progresses epitaxially from this seed crystal.

A crystalline region of a desired size can be produced on the a-Si film 29 without using, for example, patterning, when repeating irradiation of a laser beam on a region defined on the a-Si film 29 and movement of a region that is to be irradiated with a laser beam, that is, the sample 21, in this manner.

It should be noted that the step of solidification and crystallization of a-Si after melting in each region does not mean completion of solidification and crystallization of the entire region. More specifically, by utilizing the characteristics of the first and the second laser light sources 11 and 12, which are excimer lasers, that the laser sources are capable of emitting laser beams in a very short cycle, when solidification is progressing in a region, that is, when a part of the region is crystallized, the next region may be irradiated with a laser beam.

In this manner, when the time interval between irradiation of the first region 31 and the second region 32 with a laser beam is set to a short time that may be substantially simultaneous, it is possible to set the offset value to W+δW, which is larger than the above-described W[(W+δW)>W], so that a crystalline region that can be produced per unit time can be enlarged. More specifically, it is possible to increase the processing amount so as to increase the throughput. Furthermore, since the crystal growth needs to use the seed crystal, the offset value W is set with a micron order precision, but the setting precision can be moderated by shortening the time interval between irradiation of laser beams.

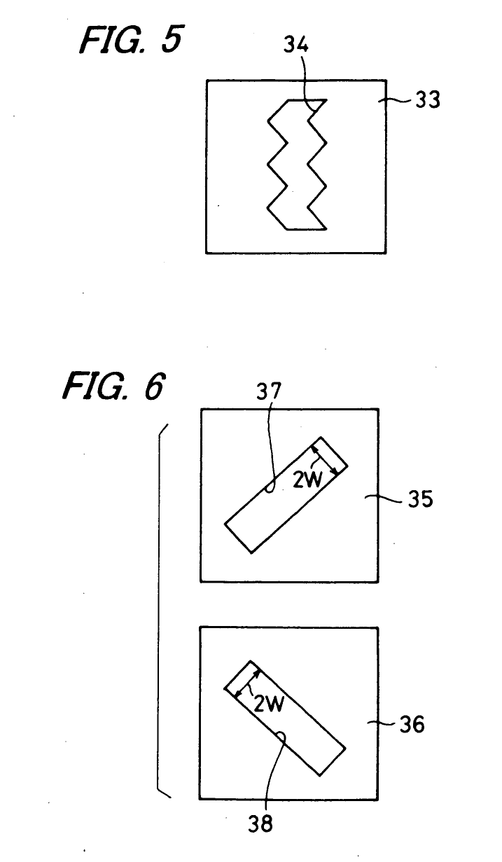

In this embodiment, the first and the second regions 31 and 32 are defined to have a shape of a rectangle as described above by the first and the second opening portions 25 and 26 formed in the first and the second projection masks 17 and 18, but the shape is not limited to this. FIG. 5 is a plan view showing the shape of an alternative projection mask 33. FIG. 5 shows that an alternative opening portion 34 formed in the alternative projection mask 33 is in the shape of sawtooth. In this manner, a region defined on the a-Si film 29 by the projection mask 33 maybe in the shape of sawtooth. When notches of the sawtooth shape are oriented to the direction in which a-Si crystallizes preferentially, the crystal growth can be facilitated. Therefore, the crystal can grow more reliably when a crystallization process is performed in the next region, using a crystal having crystallized in the previous region as the seed crystal.

FIG. 6 is a plan view showing the shapes of a third and a fourth projection mask 35 and 36 provided in a laser processing apparatus, which is a second embodiment of the invention. The laser processing apparatus of this embodiment is constituted in the same manner as in the laser processing apparatus 10 of the first embodiment except that the third and the fourth projection masks 35 and 36 are used instead of the first and the second projection masks 17 and 18, and thus the drawing and the explanation thereof are omitted.

A point to be noted is that the third and the fourth projection masks 35 and 36 are provided in the optical paths of laser beams emitted from the first and the second laser light sources 11 and 12 in such a manner that a first region and a second region defined on the a-Si film 29 by a third and a fourth rectangular opening portion 37 and 38 each formed in the third and the fourth projection masks 35 and 36 intersect each other. In this embodiment, the third and the fourth projection masks 35 and 36 are provided in such a manner that the first region and the second region defined on the a-Si film 29 intersect each other at right angles.

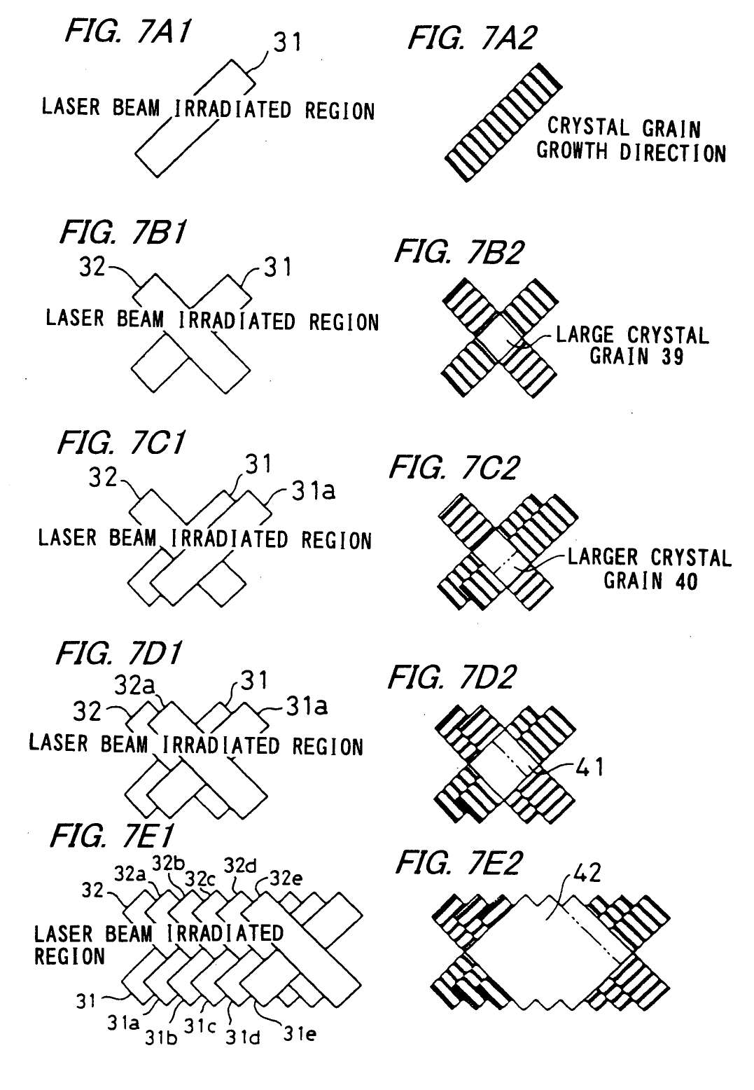

FIGS. 7A1 to 7E2 are diagrams schematically showing a crystallization process on the a-Si film 29 performed by irradiation of a laser beam, in the case where the first region 31 and the second region 32 intersect each other.

FIG. 7A1 shows the first region 31, which is a region irradiated with a laser beam on the a-Si film 29. FIG. 7A2 shows a state in which a-Si is melted by irradiation of a laser beam on the first region 31, is then solidified and crystallized. In this case, the first region 31 is rectangular, and thus a crystal grain grows in the lateral direction of the first region 31.

FIG. 7B1 shows a state in which the second region 32 intersects the first region 31. More specifically, the second region 32 is set to in a position obtained by rotating the first region 31 about an axis that is perpendicular to the sheet showing FIGS. 7A1 to 7E2 by 90° so as to have an intersecting portion as an overlapped portion. FIG. 7B2 shows a state in which the second region 32 is irradiated with a laser beam, and thus a large crystal grain 39 that has grown by using a crystal having crystallized in the first region 31 as the seed crystal is formed in the overlapped portion formed by the intersection of the first region 31 and the second region 32.

FIG. 7C1 shows a first region 31a newly defined in a position obtained by moving the stage 22 such that the sample 21 is moved by \sqrt{2}·W in a direction forming an angle of 45° with both the first region 31 and the second region 32. FIG. 7C2 shows a state in which a laser beam is irradiated on the new first region 31a, so that the crystal growth progresses into the new first region 31a by using the large crystal grain 39 having formed in the overlapped portion as the seed crystal, and thus a larger crystal grain 40 is formed.

FIG. 7D1 shows a state in which a second region 32a newly defined on the a-Si film 29 by the movement of the sample 21 intersects the new first region 31a. FIG. 7D2 shows a state in which a laser beam is irradiated on the new second region 32a, so that the crystal growth progresses into the new second region 32a by using the larger crystal grain 40 as the seed crystal, and thus an even larger crystal grain 41 is formed.

FIG. 7E1 shows an irradiated region of a laser beam that is formed by repeating the operations shown in the explanations on FIGS. 7A1 to 7D1 in which the first regions 31, 31a, 31b, 31c, 31d and 31e intersect the second regions 32, 32a, 32b, 32c, 32d and 32e in this order. FIG. 7E2 shows a state in which a large crystalline region 42 can be formed on the a-Si film 29 by forming a region irradiated with a laser beam as shown in FIG. 7E1.

When the first region 31 and the second region 32 intersect each other in this manner, a crystalline region can be enlarged sequentially along with a peripheral portion of the overlapped region in the intersection, which is a region that is to be crystallized. When a crystalline region is enlarged in this manner, a region that is to be crystallized by irradiation of a laser beam, that is, the sample 21 that is to be crystallized can be moved by an effective method of moving the stage 22 sequentially in one direction, and thus the production efficiency in a crystallization process of a-Si can be improved.

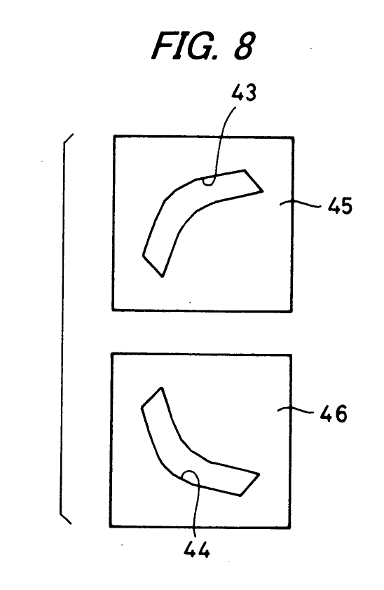

The shape of opening portions formed in projection masks provided in such a manner that the first region 31 and the second region 32 formed on the a-Si film 29 intersect each other is not limited to a rectangle as described above. FIG. 8 is a view showing the shapes of a fifth and a sixth projection mask 45 and 46 in which opening portions 43 and 44 are formed in the shape of an arch. The shape of a first and a second region intersecting each other and defined on the a-Si film 29 by the fifth and the sixth projection masks 45 and 46 as shown in FIG. 8 may be in the shape of an arch.

When one of arched curves of the first and the second regions is oriented to the direction in which a crystal grows preferentially, the crystal growth can be facilitated during solidification of a-Si after melting. Therefore, the crystal can grow more reliably when the crystal grows along with a peripheral portion of the seed crystal, using the crystal having crystallized in the intersecting portion of the first region and the second region as the seed crystal.

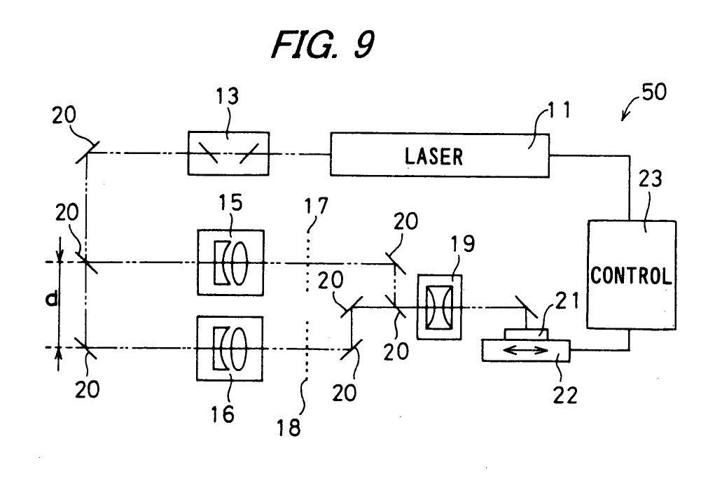

FIG. 9 is a system diagram schematically showing a structure of a laser processing apparatus 50, which is a third embodiment of the invention. The laser processing apparatus 50 of this embodiment is similar to the laser processing apparatus 10 of the first embodiment, and thus corresponding portions bear the same reference numbers and the explanations thereof are omitted.

Points to be noted regarding the laser processing apparatus 50 are that the number of light sources for emitting a laser beam is one, and that the number of provided variable attenuators for adjusting the irradiance of a laser beam emitted from the light source is also only one. In the laser processing apparatus 10 of the first embodiment provided with two light sources, the control means 23 controls a timing for emitting laser beams from the first laser light source 11 and the second laser light source 12, and then the time interval between irradiation of the first region 31 and the second region 32 with the laser beams is controlled by the timing control. On the other hand, in the laser processing apparatus 50 of this embodiment provided with only one light source, an optical path difference d is provided between laser beams reaching the sample 21 from the first laser light source 11, and then the time interval between irradiation of the first region 31 and the second region 32 with the laser beams is controlled with this optical path difference d.

FIG. 9 shows that the optical path length of a laser beam irradiated on the second region 32 defined on the a-Si film 29 by the second projection mask 18 is longer by the optical path difference d than the optical path length of a laser beam irradiated on the first region 31 defined on the a-Si film 29 on the sample 21 by the first projection mask 17. Therefore, the laser beam reaches the second region 32 later than the first region 31 by a time obtained by dividing the optical path difference d by the laser speed, and thus the time interval between irradiation of the first region 31 and the second region 32 with laser beams can be controlled even with one light source.

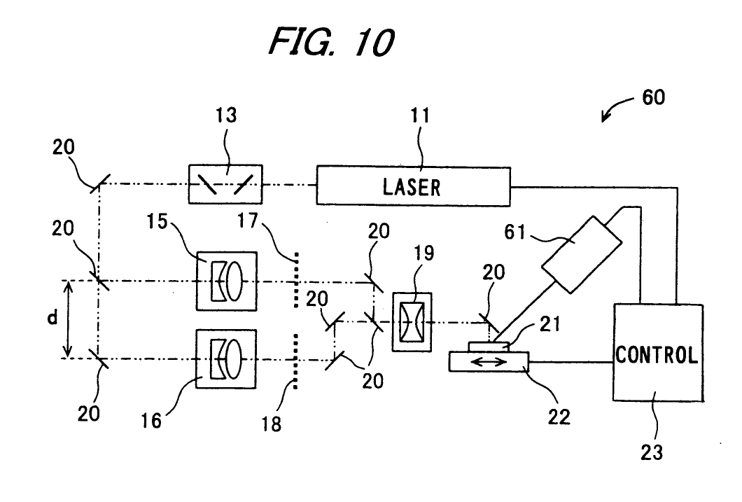

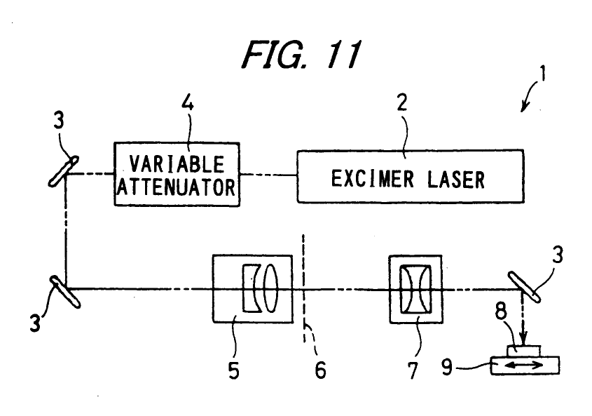

FIG. 10 is a system diagram schematically showing a structure of a laser processing apparatus 60, which is a fourth embodiment of the invention. The laser processing apparatus 60 of this embodiment is similar to the laser processing apparatus 50 of the third embodiment, and thus corresponding portions bear the same reference numbers and the explanations thereof are omitted.

Points to be noted regarding the laser processing apparatus 60 are that an additional laser light source 61 for emitting a laser beam that is to be irradiated on a-Si in a molten state in the first and/or the second regions 31 and/or 32 is provided, and that the wavelength of laser light emitted from the additional laser light source 61 is longer than the wavelength of laser light emitted from the laser light source 11.

In this embodiment, for the laser light source 11, an excimer laser that can emit laser light having a wavelength of 308 nm, which is in the ultraviolet region, can be used. For the additional laser light source 61, lasers that can emit laser light having a wavelength being longer than the wavelength of laser light emitted from the laser light source 11 and being between the infrared region and the visible region, such as a YAG laser with a wavelength of 532 nm, a YAG laser with a wavelength of 1064 nm, and a carbon dioxide gas laser with a wavelength of 10.6 μm can be used.

Laser light having a relatively short wavelength emitted from the laser light source 11 has a higher rate of absorption into the a-Si film 29 in a solid state than in a molten state, compared with laser light having a long wavelength emitted from the additional laser light source 61. On the contrary, laser light having a relatively long wavelength emitted from the additional laser light source 61 has a higher rate of absorption into the a-Si film 29 in a molten state than in a solid state, compared with laser light having a short wavelength emitted from the laser light source 11.

It is preferable that the laser beam emitted from the laser 11 has an energy amount (=energy amount/irradiated area) per irradiation that is sufficient for the a-Si film 29 in a solid state to melt, and that the laser beam emitted from the additional laser light source 61 has at most an energy amount (=energy amount/irradiated area) per irradiation that is necessary for the a-Si film 29 in a solid state to melt.

In the laser processing apparatus 60, the laser beam emitted from the laser light source 11 is incident perpendicularly to the sample 21 having the a-Si film 29, and is irradiated in such a manner that an image of the first or the second projection mask 17 or 18 forming a predetermined pattern is projected on the a-Si film 29 in a reduced size as a region irradiated with the laser beam.

On the other hand, a laser beam emitted from the additional laser light source 61 is incident diagonally to the sample 21 and is directly irradiated on the sample 21 without passing through variable focus field lens or projection masks. It is preferable that a region irradiated with a laser beam emitted from the additional laser light source 61 includes the first and the second regions 31 and 32, and have a larger area than the first and the second regions 31 and 32.

When the laser beam with a long wavelength emitted from the additional laser light source 61 is irradiated on the first and/or the second regions 31 and/or 32 containing a-Si in a molten state, the energy of the laser light is effectively absorbed by a-Si in a molten state. In this manner, the laser beam emitted from the additional laser light source 61 can heat a-Si in a molten state to reduce the cooling rate thereof, and thus an even larger crystal grain can be obtained.

In this embodiment, the laser light sources 11 and 12 are excimer lasers as described above, but are not limited to this, and other gas lasers or solid-state lasers may be used. Furthermore, an amorphous material is a-Si, but is not limited to this, and amorphous germanium or selenium may be used.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

### INDUSTRIAL APPLICABILITY

According to the invention, a first region is irradiated with a laser beam so that an amorphous material is melted, solidified and crystallized, and then a second region overlapping the first region at a predetermined portion is irradiated with a laser beam so that an amorphous material is melted, solidified and crystallized. In this manner, when the amorphous material in the second region is melted by irradiation of a laser beam and then solidified, a crystal can grow epitaxially by taking over the crystal grain having formed in the first region, using the crystal having formed in the first region as the seed crystal. Furthermore, a region that is to be irradiated with a laser beam is moved in a predetermined direction by a predetermined distance, and a first region is newly defined so as to partially overlap the immediately previous second region, and the crystallization process of irradiation of a laser beam on the first region and the second region and movement of the region that is to be irradiated is repeated sequentially. Thus, a crystalline region of a desired size can be produced in a layer formed of an amorphous material without constraints by, for example, patterning. In addition, a crystal can grow sequentially by using a portion that has crystallized previously as the seed crystal, and thus a large crystal grain can be produced.

Furthermore, according to the invention, the first and the second regions are defined as a rectangle shape on a surface of the layer formed of the amorphous material. Thus, when the amorphous material is melted and solidified, the first and the second regions are provided with a temperature gradient that is larger in the lateral direction than in the longitudinal direction. Consequently, the crystallization and the crystal growth progress preferentially in the lateral direction having a large temperature gradient. Thus, a larger crystal grain can be produced than in the case in which a region is defined, for example, in the shape of a square, and the crystallization progresses from four sides in a substantially uniform manner.

Furthermore, according to the invention, the first and the second regions are defined as a sawtooth shape or an arch shape on a surface of the layer formed of the amorphous material. When notches of the sawtooth shape or an arched curve of the first and the second regions are oriented to the direction in which a crystal grows preferentially, the crystal growth can be facilitated during solidification of the amorphous material after melting. Thus, the crystal can grow more reliably when the crystallization process is performed in the second region, using the crystal having crystallized in the first region as the seed crystal.

Furthermore, according to the invention, the first region and the second regions intersect each other, and thus the crystalline region can be enlarged sequentially along with a peripheral portion of the overlapped region in the intersection, which is a region having crystallized. When the crystalline region is enlarged in this manner, a region that is to be crystallized by irradiation of a laser beam can be moved effectively. Thus, the production efficiency of a crystallized semiconductor material can be improved.

Furthermore, according to the invention, the amorphous material in a molten state is irradiated with an additional laser beam. Thus, the cooling rate of the amorphous material in a molten state can be reduced. Thus, a larger crystal grain can be obtained when the amorphous material is crystallized.

Furthermore, according to the invention, a laser beam processing apparatus includes a light source for emitting a laser beam, a first projection mask for defining a first region on a surface of a layer formed of an amorphous material, and a second projection mask for defining a second region. Thus, it is possible to perform crystallization and crystal growth smoothly in which the first region is irradiated with a laser beam for the crystallization, and then the second region is irradiated with a laser beam for the crystal growth by using the crystal having produced in the first region as the seed crystal.

Furthermore, according to the invention, since two light sources, that is, a first laser light source and a second laser light source are provided, the time interval between irradiation of the first region and the second region with a laser beam can be set freely, so that the second region can be irradiated with a laser beam, using the crystal having crystallized in the first region as a seed crystal, at an optimal timing for the crystal to grow from the seed crystal. Thus, a large crystal grain can be produced. Furthermore, since the optimal timing for the second region to be irradiated with a laser beam can be set after irradiating the first region with a laser beam as described above, it is possible to moderate the acceptable range regarding a region in which the second region preferably overlaps the first region for the crystal growth from the crystal seed.

Furthermore, according to the invention, an additional laser light source for emitting a laser beam for irradiating an amorphous material in a molten state in the first and/or the second regions is provided, and the wavelength of laser light emitted from the additional laser light source is longer than the wavelength of laser light emitted from the above-described laser light source. Laser light with a short wavelength is easily absorbed by an amorphous material in a solid state, and laser light with a long wavelength is easily absorbed by an amorphous material in a molten state. Thus, when an amorphous material in a molten state is irradiated with laser light with a long wavelength emitted from the additional laser light source, the energy of the laser light is effectively absorbed by the amorphous material in a molten state. In this manner, the cooling rate of the amorphous material in a molten state can be reduced. Thus, it is possible to realize a laser processing apparatus with which an even larger crystal grain can be obtained.

1. A laser processing method for crystallizing an amorphous material by irradiating a layer formed of the amorphous material constituting a substrate or a layer formed of an amorphous material on a substrate with a laser beam, comprising:
irradiating a first region defined on a surface of the layer formed of the amorphous material with a laser beam so that the amorphous material in the first region is melted;
solidifying and crystallizing the molten amorphous material in the first region;
irradiating a second region that is defined on the surface of the layer formed of the amorphous material and overlaps the first region in a predetermined portion thereof with a laser beam so that the amorphous material in the second region is melted;
solidifying and crystallizing the molten amorphous material in the second region;
moving a region that is to be irradiated with a laser beam in a predetermined direction by a predetermined distance, and newly defining a first region on the surface of the layer formed of the amorphous material so as to partially overlap a immediately previous second region; and
repeating irradiation of the laser beam on the surface of the layer formed of the amorphous material and movement of a region that is to be irradiated with the laser beam until a crystalline region of the amorphous material reaches a desired size.

2. The laser processing method of claim 1, wherein the first and the second regions are defined as a rectangle shape on the surface of the layer formed of the amorphous material.

3. The laser processing method of claim 1, wherein the first and the second regions on the surface of the layer formed of the amorphous material are defined as a sawtooth shape.

4. The laser processing method of claim 1, wherein the first and the second regions are defined on the surface of the layer formed of the amorphous material as an arch shape.

5. The laser processing method of any one of claims 1 to 4, wherein the first region and the second region intersect with each other.

6. The laser processing method of any one of claims 1 to 5, wherein the amorphous material in a molten state in the first and/or the second regions is irradiated with an additional laser beam.

7. A laser processing apparatus which crystallizes an amorphous material by irradiating a layer formed of the amorphous material constituting a substrate or a layer formed of an amorphous material on a substrate with a laser beam, comprising:
a light source for emitting a laser beam;
a first projection mask provided in an optical path of a laser beam formed between the light source and the layer formed of the amorphous material so as to define a first region on a surface of the layer formed of the amorphous material by letting the laser beam emitted from the light source pass through; and
a second projection mask provided in an optical path of a laser beam formed between the light source and the layer formed of the amorphous material so as to define a second region on the surface of the layer formed of the amorphous material by letting the laser beam emitted from the light source pass through.

8. The laser processing apparatus of claim 7, wherein the laser light source includes a first laser light source for emitting a laser beam for irradiating the first region and a second laser light source for emitting a laser beam for irradiating the second region.

9. The laser processing apparatus of claim 7 or 8, further comprising an additional laser light source for emitting a laser beam for irradiating the amorphous material in a molten state in the first and/or the second regions,
wherein a wavelength of laser light emitted from the additional laser light source is longer than a wavelength of laser light emitted from said laser light source.
